(19) United States
(12) Patent Application Publication
(10) Pub. No.: US 2016/0226526 A1
(43) Pub. Date: Aug. 4, 2016

(54) Systems and Methods for Soft Data Based Cross Codeword Error Correction

(71) Applicant: Avago Technologies General IP (Singapore) Pte. Ltd., SINGAPORE (SG)

(72) Inventors: Yang Han, Sunnyvale, CA (US); Shaohua Yang, San Jose, CA (US); Xuebin Wu, San Jose, CA (US)

(21) Appl. No.: 14/611,949

(22) Filed: Feb. 2, 2015

(51) Int. Cl. H03M 13/35; H03M 13/37; H03M 13/11

(52) U.S. Cl. CPC H03M 13/353; H03M 13/1102; H03M 13/3784

(57) ABSTRACT

Embodiments are related to systems and methods for data processing, and more particularly to systems and methods for error correction in a data processing system.

### FIELD OF THE INVENTION

Embodiments are related to systems and methods for data processing, and more particularly to systems and methods for error correction in a data processing system.

### BACKGROUND

Various storage access systems have been developed that include an ability to sense data previously stored on a storage medium. Such storage access systems generally include circuitry and/or software used to process a sensed signal from a storage medium, and to process the sensed data in an attempt to recover an originally written data set. In some cases, the data includes too many errors to be corrected and the data is thus not recoverable.

Hence, for at least the aforementioned reasons, there exists a need in the art for advanced systems and methods for data processing.

### SUMMARY

Embodiments are related to systems and methods for data processing, and more particularly to systems and methods for error correction in a data processing system.

Various embodiments provide data processing systems. Such systems include a data processing circuit that itself includes: a cross codeword error correction circuit, and a data decoding circuit. The data processing circuit is operable to receive a data set including a plurality of user data codewords and a cross codewords error correction codeword including encoding generated from the plurality of user data codewords. The cross codeword error correction circuit is operable to calculate a soft data adjustment value based at least in part upon the cross codewords error correction codeword. The data decoding circuit is operable to apply a data decoding algorithm to at least one of the user data codewords guided by a decoder input generated in part from the soft data adjustment value.

This summary provides only a general outline of some embodiments of the invention. The phrases “in one embodiment,” “according to one embodiment,” “in various embodiments”, “in one or more embodiments”, “in particular embodiments” and the like generally mean the particular feature, structure, or characteristic following the phrase is included in at least one embodiment of the present invention, and may be included in more than one embodiment of the present invention. Importantly, such phrases do not necessarily refer to the same embodiment. Many other embodiments of the invention will become more fully apparent from the following detailed description, the appended claims and the accompanying drawings.

### BRIEF DESCRIPTION OF THE FIGURES

A further understanding of the various embodiments of the present invention may be realized by reference to the figures which are described in remaining portions of the specification. In the figures, like reference numerals are used throughout several figures to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1 shows a storage system including soft data based cross codewords error correction circuitry in accordance with various embodiments of the present inventions;

FIG. 2a shows a data encoding circuit providing cross codewords encoding in accordance with some embodiments of the present inventions;

FIG. 2b shows an example output of the data encoding circuit of FIG. 2a;

FIG. 3 is a flow diagram showing a method for data encoding in accordance with some embodiments of the present inventions;

FIG. 4a shows another data encoding circuit providing cross codewords encoding in accordance with some embodiments of the present inventions;

FIG. 4b shows an example output of the data encoding circuit of FIG. 4a;

FIG. 5 is a flow diagram showing another method for data encoding in accordance with some embodiments of the present inventions;

FIG. 6 shows a data processing circuit applying cross codeword decoding in accordance with some embodiments of the present inventions;

FIGS. 7a-7b are flow diagrams showing a method in accordance with various embodiments of the present inventions for applying first attempt data decoding; and

FIG. 8 is a flow diagram showing a method in accordance with various embodiments of the present inventions for applying soft data based cross codeword decoding.

### DETAILED DESCRIPTION OF SOME EMBODIMENTS

Embodiments are related to systems and methods for data processing, and more particularly to systems and methods for error correction in a data processing system.

Various embodiments provide data processing systems. Such systems include a data processing circuit that itself includes: a cross codeword error correction circuit, and a data decoding circuit. The data processing circuit is operable to receive a data set including a plurality of user data codewords and a cross codewords error correction codeword including encoding generated from the plurality of user data codewords. The cross codeword error correction circuit is operable to calculate a soft data adjustment value based at least in part upon the cross codewords error correction codeword. The data decoding circuit is operable to apply a data decoding algorithm to at least one of the user data codewords guided by a decoder input generated in part from the soft data adjustment value.

In some instances of the aforementioned embodiments, the soft data adjustment value is a first soft data adjustment value. In some such cases, the data processing circuit further includes a data detector circuit operable to apply a data detection algorithm to at least one of the user data codewords guided by a detector input generated in part from the second soft data adjustment value. In some cases, the data detector circuit provides a detector output, and the decoder input is generated in part by adding the first soft data adjustment value to the detector output. In one particular case, the decoder input is generated by multiplying the result of adding the first soft data adjustment value to the detector output by a scaling value. In various instances, the data decoding circuit provides a decoder output, and the detector input is generated in part by adding the second soft data adjustment value to the decoder output. In some such cases, the detector input is generated by multiplying the result of adding the second soft data adjustment value to the decoder output by a scaling value. In one particular case, the scaling value is user programmable. In one or more instances of the aforementioned embodiments, the data detection algorithm is a maximum a posteriori data detection algorithm.

In one or more instances of the aforementioned embodiments, the system is implemented as part of an integrated circuit. In various cases, the system is implemented as part of a storage device. In some such cases, the storage device includes: a storage medium storing the plurality of user data codewords and the cross codewords error correction codeword, and a read/write head assembly disposed in relation to the storage medium. In particular cases, each bit position of the plurality of each of the user data codewords are XORd as part of generating a value included at a corresponding bit position of the cross codewords error correction codeword.

In one or more instances of the aforementioned embodiments, each of the user data codewords are low density parity check codewords, and the cross codewords error correction codeword is generated prior to applying the low density parity check encoding that yields the user data codewords. In various cases, the parity data added during the low density parity check encoding is not protected by the cross codewords error correction codeword.

In some instances of the aforementioned embodiments, the cross codewords error correction codeword incorporates two or more codewords shuffled together to distribute encoding protection across the two or more codewords. In various instances of the aforementioned embodiments, the cross codewords error correction codeword is scrambled, and the data processing circuit further includes a descrambling circuit operable to reverse the scrambling of the cross codewords error correction coding.

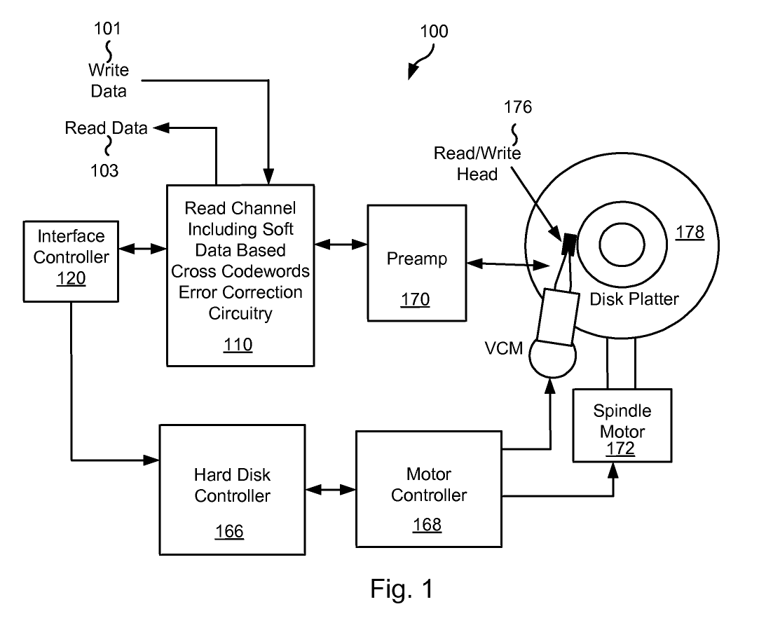

Turning to FIG. 1, a storage system 100 including a read channel circuit 110 having soft data based cross codewords error correction circuitry in accordance with various embodiments of the present invention. Storage system 100 may be, for example, a hard disk drive. Storage system 100 also includes a preamplifier 170, an interface controller 120, a hard disk controller 166, a motor controller 168, a spindle motor 172, a disk platter 178, and a read/write head 176. Interface controller 120 controls addressing and timing of data to/from disk platter 178. The data on disk platter 178 consists of groups of magnetic signals that may be detected by read/write head assembly 176 when the assembly is properly positioned over disk platter 178. In one embodiment, disk platter 178 includes magnetic signals recorded in accordance with either a longitudinal or a perpendicular recording scheme.

In a typical read operation, read/write head assembly 176 is accurately positioned by motor controller 168 over a desired data track on disk platter 178. Motor controller 168 both positions read/write head assembly 176 in relation to disk platter 178 and drives spindle motor 172 by moving read/write head assembly to the proper data track on disk platter 178 under the direction of hard disk controller 166. Spindle motor 172 spins disk platter 178 at a determined spin rate (RPMs). Once read/write head assembly 176 is positioned adjacent the proper data track, magnetic signals representing data on disk platter 178 are sensed by read/write head assembly 176 as disk platter 178 is rotated by spindle motor 172. The sensed magnetic signals are provided as a continuous, minute analog signal representative of the magnetic data on disk platter 178. This minute analog signal is transferred from read/write head assembly 176 to read channel circuit 110 via preamplifier 170. Preamplifier 170 is operable to amplify the minute analog signals accessed from disk platter 178. In turn, read channel circuit 110 decodes and digitizes the received analog signal to recreate the information originally written to disk platter 178. This data is provided as read data 103 to a receiving circuit. A write operation is substantially the opposite of the preceding read operation with write data 101 being provided to read channel circuit 110. This data is then encoded and written to disk platter 178.

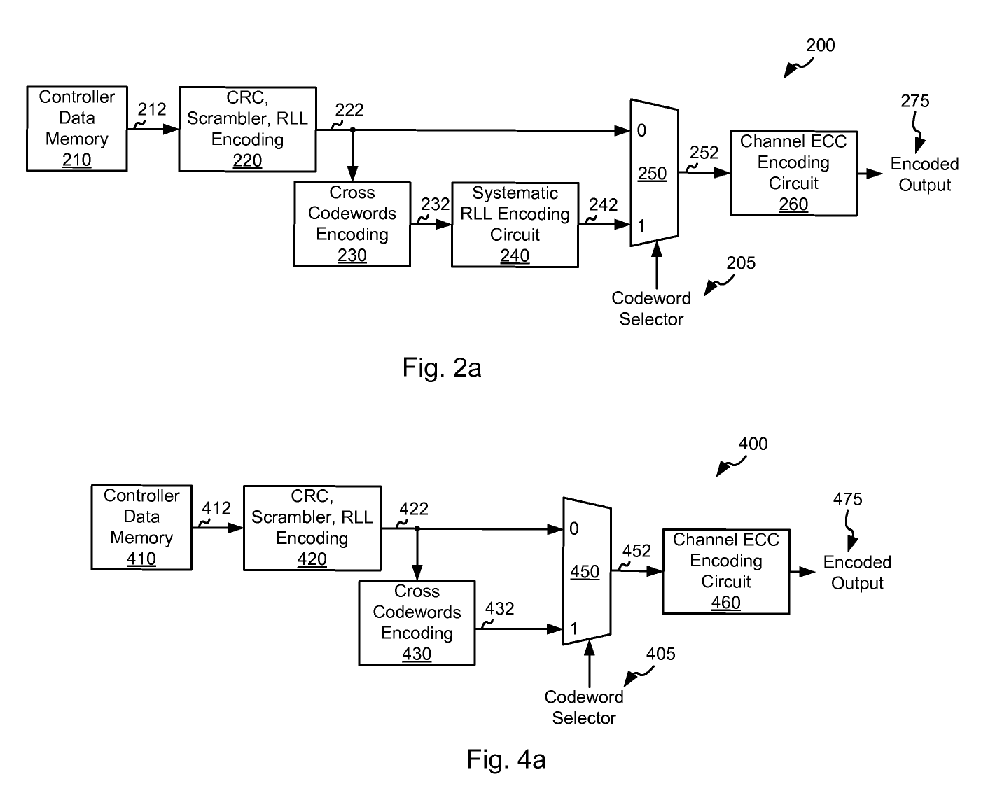

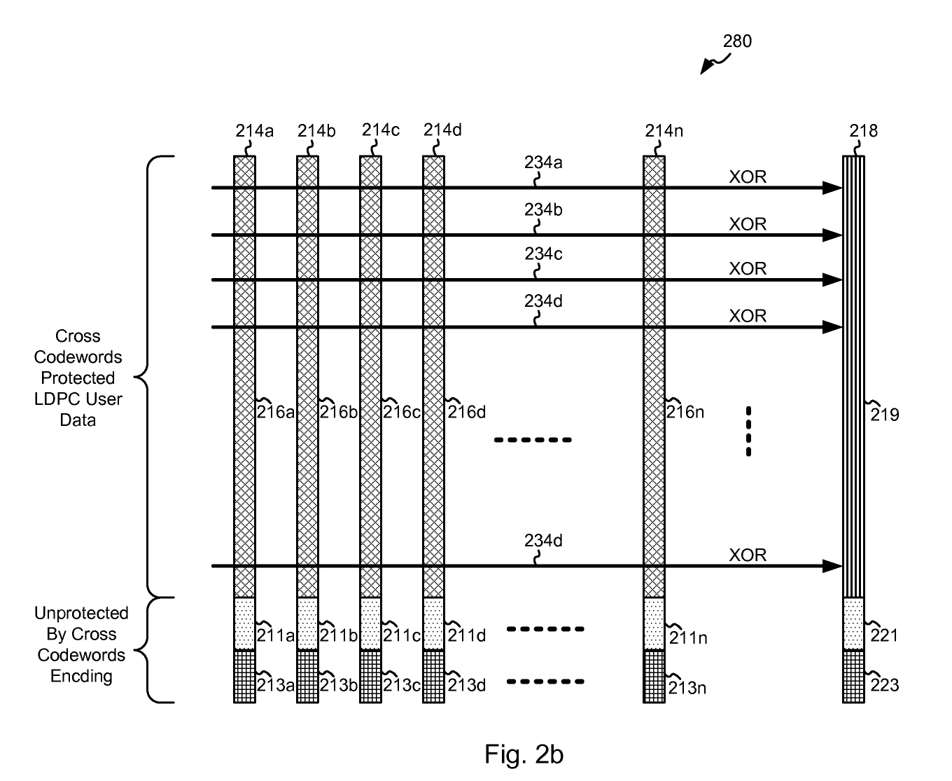

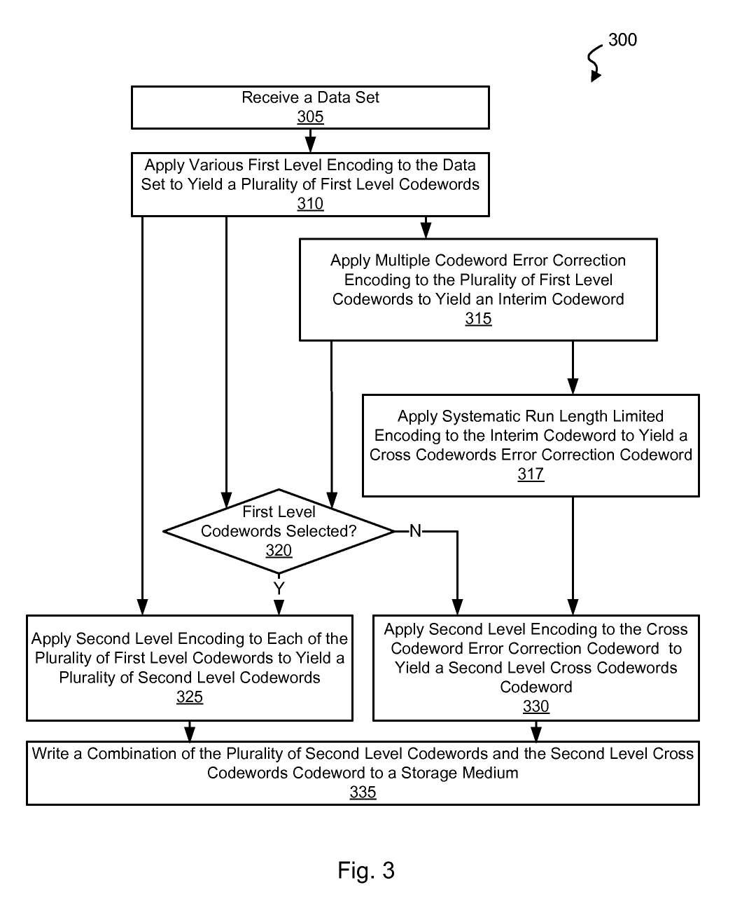

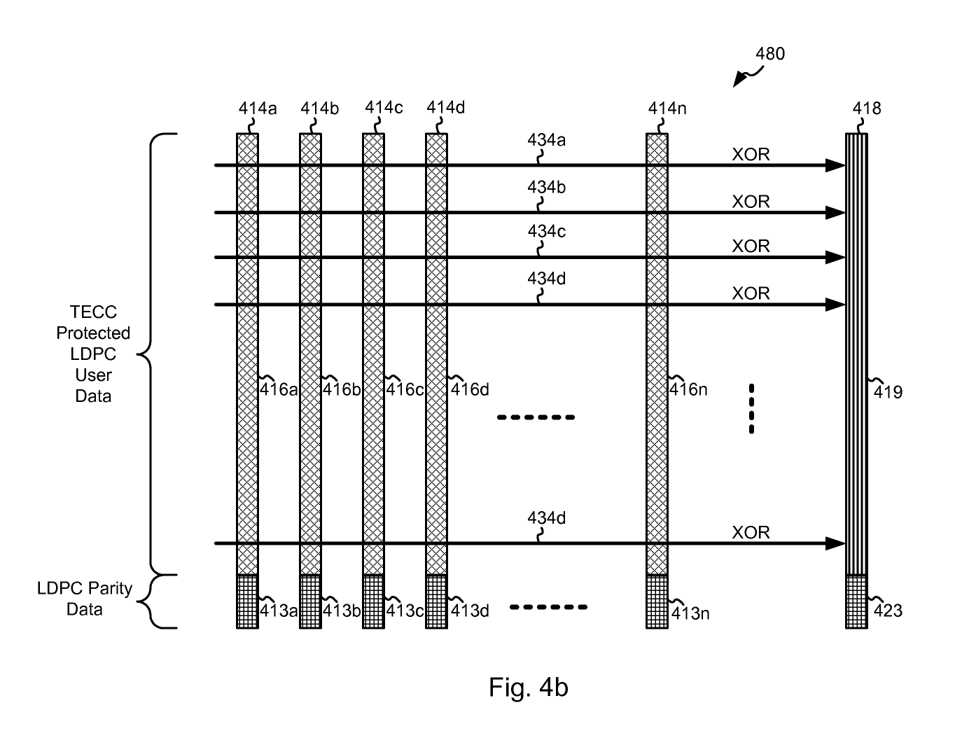

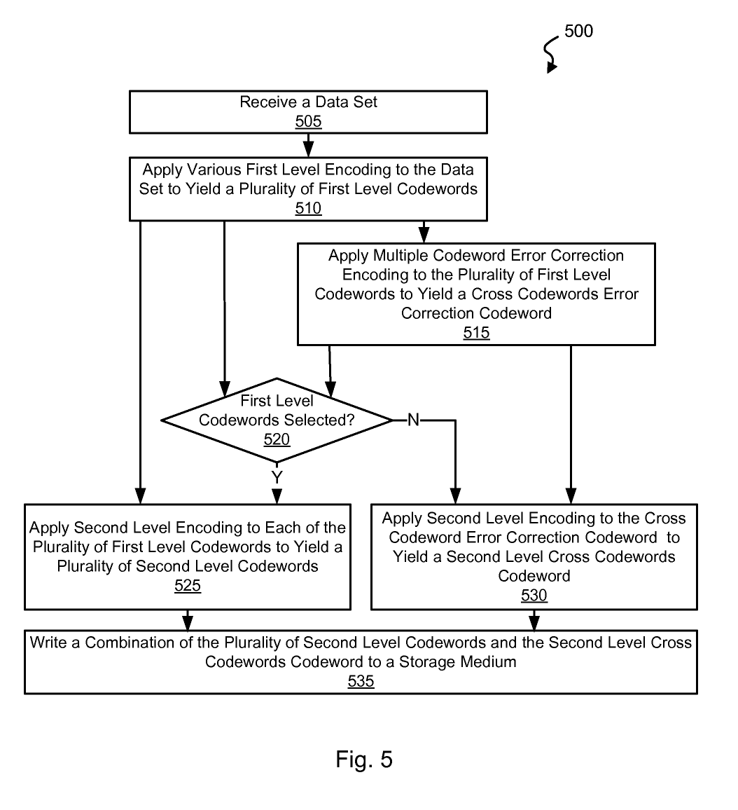

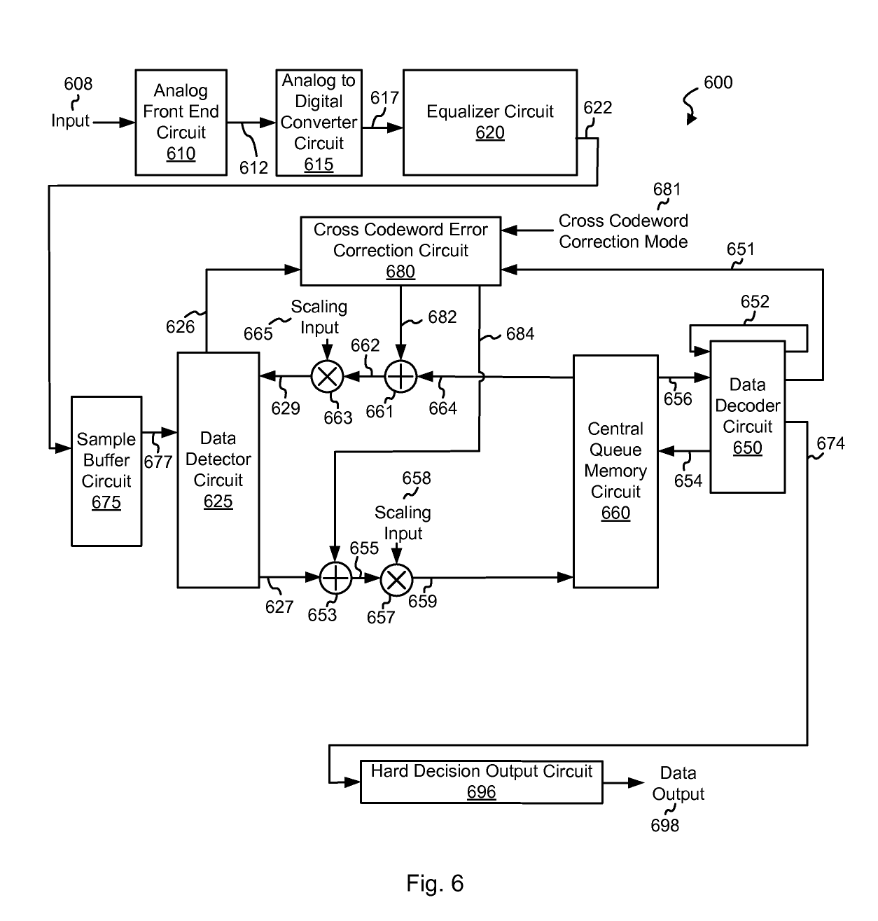

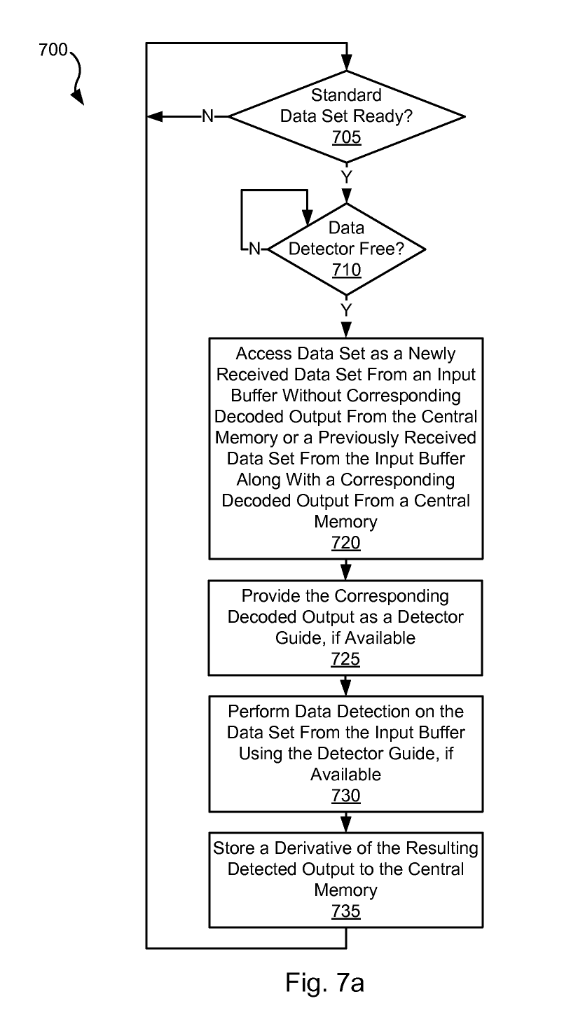

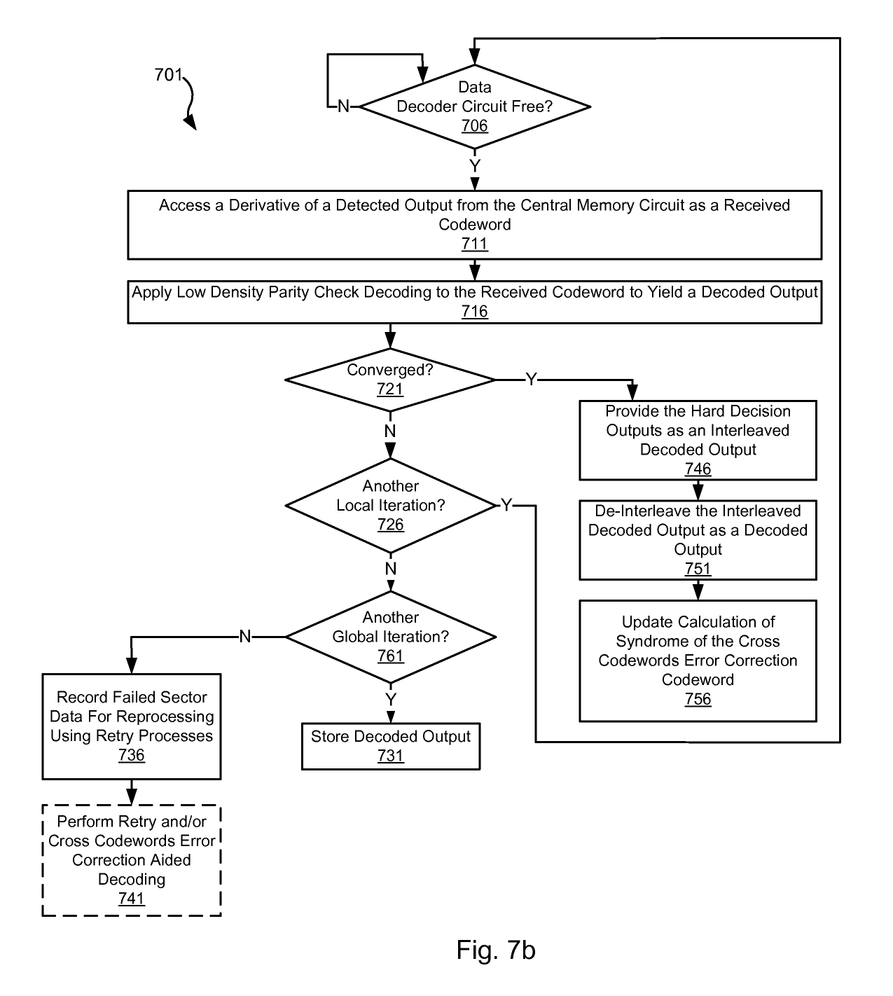

Data written to disk platter 178 includes a cross codewords error correction encoding that is used to correct non-converging codewords using other converging codewords. In operation, a user data set is encoded using standard encoding techniques, and additionally is encoded to add another codeword based upon the codewords including user data and acting as a check on the other codewords. Where the decoding of any of the user data codewords fails to converge, soft data generated based upon other failed codewords and the additional codeword are used to correct errors in the non-converging codewords. In some cases, the data encoding is performed using a circuit similar to that discussed below in relation to FIG. 2a or 4a, and/or may be done using a process similar to that discussed below in relation to FIG. 3 or 5. In various cases, the decoding is performed using a data decoder circuit similar to that discussed below in relation to FIG. 6, and/or may be done using a process similar to that discussed below in relation to FIGS. 7a-7b and 8 or 9.

It should be noted that storage system 100 may be integrated into a larger storage system such as, for example, a RAID (redundant array of inexpensive disks or redundant array of independent disks) based storage system. Such a RAID storage system increases stability and reliability through redundancy, combining multiple disks as a logical unit. Data may be spread across a number of disks included in the RAID storage system according to a variety of algorithms and accessed by an operating system as if it were a single disk. For example, data may be mirrored to multiple disks in the RAID storage system, or may be sliced and distributed across multiple disks in a number of techniques. If a small number of disks in the RAID storage system fail or become unavailable, error correction techniques may be used to recreate the missing data based on the remaining portions of the data from the other disks in the RAID storage system. The disks in the RAID storage system may be, but are not limited to, individual storage systems such as storage system 100, and may be located in close proximity to each other or distributed more widely for increased security. In a write operation, write data is provided to a controller, which stores the write data across the disks, for example by mirroring or by striping the write data. In a read operation, the controller retrieves the data from the disks. The controller then yields the resulting read data as if the RAID storage system were a single disk.

A data decoder circuit used in relation to read channel circuit 110 may be, but is not limited to, a low density parity check (LDPC) decoder circuit as are known in the art. Such low density parity check technology is applicable to transmission of information over virtually any channel or storage of information on virtually any media. Transmission applications include, but are not limited to, optical fiber, radio frequency channels, wired or wireless local area networks, digital subscriber line technologies, wireless cellular, Ethernet over any medium such as copper or optical fiber, cable channels such as cable television, and Earth-satellite communications. Storage applications include, but are not limited to, hard disk drives, compact disks, digital video disks, magnetic tapes and memory devices such as DRAM, NAND flash, NOR flash, other non-volatile memories and solid state drives.

In addition, it should be noted that storage system 100 may be modified to include solid state memory that is used to store data in addition to the storage offered by disk platter 178. This solid state memory may be used in parallel to disk platter 178 to provide additional storage. In such a case, the solid state memory receives and provides information directly to read channel circuit 110. Alternatively, the solid state memory may be used as a cache where it offers faster access time than that offered by disk platter 178. In such a case, the solid state memory may be disposed between interface controller 120 and read channel circuit 110 where it operates as a pass through to disk platter 178 when requested data is not available in the solid state memory or when the solid state memory does not have sufficient storage to hold a newly written data set. Based upon the disclosure provided herein, one of ordinary skill in the art will recognize a variety of storage systems including both disk platter 178 and a solid state memory.

Turning to FIG. 2a, a data encoding circuit 200 providing cross codewords encoding in accordance with some embodiments of the present inventions. Data encoding circuit 200 includes a controller data memory 210 that receives and stores user data to be transferred to a storage medium. The stored data 212 is provided to a first level encoding circuit 220 that applies first level encoding to yield a first level encoded output 222. The encoding applied by first level encoding circuit 220 may include, for example, run length limited encoding, cyclic redundancy check encoding, scrambling and/or other known encoding processes.

First level encoded output 222 is provided to both a selector circuit 250 and a cross codewords encoding circuit 230. Cross codewords encoding circuit 230 applies an encoding algorithm to the codewords provided as first level encoded output 222 to yield a interim codeword 232. In some cases, the cross codewords encoding includes XORing all corresponding bit positions in the multiple codewords provided as first level encoded output 222 and an encoding bit is generated to yield a particular parity (e.g., odd or even parity) for the bit position including the corresponding position in interim codeword 232. The generated parity assumes the particular location in interim codeword 232, and the process is completed for each of the other bit positions in the multiple codewords provided as first level encoded output 222 to generate interim codeword 232. Interim codeword 232 is provided to a systematic run length limited encoding circuit 240 that applies run length limited encoding as is known in the art to yield a cross codewords error correction codeword 242. Cross codewords error correction codeword 242 is provided to selector circuit 250.

It should be noted that in some embodiments of the present invention that cross codewords error correction codeword 242 is provided to a scrambler circuit (not shown). Such a scrambler circuit scrambles the elements of cross codewords error correction codeword 242 to yield a scrambled output. Scrambling may be done, for example, XORing a pseudo-random sequence with the data to make the data appear random. In such embodiments, the scrambled output is provided to selector circuit 250 in place of cross codewords error correction codeword 242. Such scrambling avoids a situation where all zeros are written to a storage medium.

Selector circuit 250 selects one of cross codewords error correction codeword 242 or first level encoded output 222 to yield a channel encoder input codeword 252. Channel encoder input codeword 252 is provided to a channel ECC encoder 260 that applies an encoding algorithm to each of the codewords (i.e., each of the codewords provided as first level encoded output 222 and cross codewords error correction codeword 242) to yield an encoded output 275. Encoded output 275 is then prepared to be written to a storage medium. In some embodiments, the encoding algorithm applied by channel ECC encoder 260 is a low density parity check encoding algorithm as is known in the art. In such a case, encoded output 275 is a low density parity check encoded output.

Turning to FIG. 2b, an example output 280 generated by data encoding circuit of FIG. 2a is shown. Example output 280 includes a number of LDPC encoded codewords 214. Each of codewords 214 includes user data portion 216, user data portion 211, and LDPC parity data 213. Each bit position (e.g., bit positions 234 in user data portion 216) of LDPC codewords are XORed to yield a selected parity for a corresponding bit position in a cross codewords error correction codeword 218. A first portion 219 of cross codewords error correction codeword 218 is generated by cross codeword encoding of user data portion 216, and thus corresponds to the user data portions 216 of LDPC codewords 214. Bits of portion 221 are generated by operating a systematic RLL encoding over data 219. The bits of portion 221 are normally scattered inside with the bits of first portion 219 in the bit format ultimately stored to the storage medium. The user bits portion 211 in user codewords 214 correspond to the systematic RLL encoding generated bits of portion 221. LDPC parity data 213 are generated after cross codewords encoding. Both bits portions 211 and 213 in user codewords are not protected by corresponding portions 221, 223 of cross codewords error correction codeword 218.

In some embodiments of the present invention, two or more channel ECC component codewords are interleaved with each other and form a user codeword 214 or cross codewords error correction codeword 218. In such cases, multi-way interleaving may be applied such that each of the interleaved channel ECC component codewords have similar number of user bits in data portion 219 and data portion 216, and similarly similar number of user bits in data portion 211 and data portion 221.

Turning to FIG. 3, a flow diagram 300 shows a method for data encoding in accordance with some embodiments of the present inventions. Following flow diagram 300, a user data set is received (block 305). The user data set includes sufficient data to populate a number of codewords. Various first level encoding is applied to the received data set to yield a plurality (i.e., more than one) first level codewords (block 310). Such encoding may include, but is not limited to, run length limited encoding, cyclic redundancy check encoding, scrambling and/or other known encoding processes known in the art.

Multiple codeword error correction encoding is provided to the plurality of first level codewords to yield an interim codeword (block 315). Using FIG. 2b as an example, multiple codeword error correction encoding is applied to LDPC codewords 234 to yield an interim codeword. Systematic run length limited encoding is applied to the resulting interim codeword to yield a cross codewords error correction codeword (block 317). The run length limited encoding may be any run length limited encoding process known in the art.

It is determined whether first level codewords are selected (block 320). First level codewords are selected when codewords derived from the received user data are being processed. Alternatively, when the cross codewords error correction codeword is to be processed, the first level codewords are not selected. Where the first level codewords are selected (block 320), second level encoding is applied to each of the plurality of first level codewords to yield a corresponding plurality of second level codewords (block 325). In some embodiments, the second level encoding is low density parity check encoding as is known in the art. Alternatively, where the first level codewords are not selected (block 320), second level encoding is applied to the cross codewords error correction codeword to yield a second level cross codewords codeword (block 325). Again, in some embodiments, the second level encoding is low density parity check encoding as is known in the art. A combination of the plurality of second level codewords and the second level cross codewords codeword are stored to a storage medium (block 335).

Turning to FIG. 4a, a data encoding circuit 400 providing cross codewords encoding in accordance with some embodiments of the present inventions. Data encoding circuit 400 includes a controller data memory 410 that receives and stores user data to be transferred to a storage medium. The stored data 412 is provided to a first level encoding circuit 420 that applies first level encoding to yield a first level encoded output 422. The encoding applied by first level encoding circuit 420 may include, for example, run length limited encoding, cyclic redundancy check encoding, scrambling and/or other known encoding processes.

First level encoded output 422 is provided to both a selector circuit 450 and a cross codewords encoding circuit 430. Cross codewords encoding circuit 430 applies an encoding algorithm to the codewords provided as first level encoded output 422 to yield a cross codewords error correction codeword 432. In some cases, the cross codewords encoding includes XORing all corresponding bit positions in the multiple codewords provided as first level encoded output 422 and an encoding bit is generated to yield a particular parity (e.g., odd or even parity) for the bit position including the corresponding position in cross codewords error correction codeword 432. The generated parity assumes the particular location in cross codewords error correction codeword 432, and the process is completed for each of the other bit positions in the multiple codewords provided as first level encoded output 422 to generate cross codewords error correction codeword 432. Cross codewords error correction codeword 432 is provided to selector circuit 450.

Selector circuit 450 selects one of cross codewords error correction codeword 432 or first level encoded output 422 to yield a channel encoder input codeword 452. Channel encoder input codeword 452 is provided to a channel ECC encoder 460 that applies an encoding algorithm to each of the codewords (i.e., each of the codewords provided as first level encoded output 422 and cross codewords error correction codeword 432) to yield an encoded output 475. Encoded output 475 is then prepared to be written to a storage medium. In some embodiments, the encoding algorithm applied by channel ECC encoder 460 is a low density parity check encoding algorithm as is known in the art. In such a case, encoded output 475 is a low density parity check encoded output.

It should be noted that in some embodiments of the present invention that the output of channel ECC encoder corresponding to cross codewords error correction codeword 432 is provided to a scrambler circuit (not shown). Such a scrambler circuit scrambles the elements of encoded output 475 that correspond to the cross codewords error correction codeword 432 to yield a scrambled output. Scrambling may be done, for example, XORing a pseudo-random sequence with the data to make the data appear random. In such embodiments, the scrambled output is provided to an upstream processing circuit in place of encoded output 475. Such scrambling avoids a situation where all zeros are written to a storage medium.

Turning to FIG. 4b, an example output 480 generated by data encoding circuit of FIG. 4a is shown. Example output 480 includes a number of LDPC encoded codewords 414. Each of codewords 414 includes user data 416 and LDPC parity data 413. Each bit position (e.g., bit positions 434) of LDPC codewords are XORed to yield a selected parity for a corresponding bit position in a cross codewords error correction codeword 418. A first portion 419 of cross codewords error correction codeword 418 corresponds to the user data portions 416 of LDPC codewords 414. Even though LDPC parity data 413 are generated after cross codewords encoding, they are also possibly protected by cross codewords coding correction in some scenarios when the LDPC code is linear (all codewords are in the null space of the parity check matrix) and all codewords 414 and 418 are using the same LDPC parity check matrix. In these scenarios, the channel ECC encoding can be placed at point 422 before the cross codewords parity encoding, and the cross codewords parity encoding covers bits in all user bits (data portions 416 and 419) and LDPC parity bits positions (data portions 413 and 423).

Turning to FIG. 5, a flow diagram 500 shows a method for data encoding in accordance with some embodiments of the present inventions. Following flow diagram 500, a user data set is received (block 505). The user data set includes sufficient data to populate a number of codewords. Various first level encoding is applied to the received data set to yield a plurality (i.e., more than one) first level codewords (block 510). Such encoding may include, but is not limited to, run length limited encoding, cyclic redundancy check encoding, scrambling and/or other known encoding processes known in the art.

Multiple codeword error correction encoding is provided to the plurality of first level codewords to yield an interim codeword (block 515). Using FIG. 4b as an example, multiple codeword error correction encoding is applied to LDPC codewords 434 to yield a cross codewords error correction codeword. It is determined whether first level codewords are selected (block 520). First level codewords are selected when codewords derived from the received user data are being processed. Alternatively, when the cross codewords error correction codeword is to be processed, the first level codewords are not selected. Where the first level codewords are selected (block 520), second level encoding is applied to each of the plurality of first level codewords to yield a corresponding plurality of second level codewords (block 525). In some embodiments, the second level encoding is low density parity check encoding as is known in the art. Alternatively, where the first level codewords are not selected (block 520), second level encoding is applied to the cross codewords error correction codeword to yield a second level cross codewords codeword (block 525). Again, in some embodiments, the second level encoding is low density parity check encoding as is known in the art. A combination of the plurality of second level codewords and the second level cross codewords codeword are stored to a storage medium (block 535).

Turning to FIG. 6, a data processing circuit 600 applying cross codeword decoding is shown in accordance with some embodiments of the present inventions. Data processing circuit 600 includes an analog front end circuit 610 that receives an analog signal 608. Analog front end circuit 610 processes analog signal 608 and provides a processed analog signal 612 to an analog to digital converter circuit 615. Analog front end circuit 610 may include, but is not limited to, an analog filter and an amplifier circuit as are known in the art. Based upon the disclosure provided herein, one of ordinary skill in the art will recognize a variety of circuitry that may be included as part of analog front end circuit 610. In some cases, analog input signal 608 is derived from a read/write head assembly (not shown) that is disposed in relation to a storage medium (not shown). In other cases, analog input signal 608 is derived from a receiver circuit (not shown) that is operable to receive a signal from a transmission medium (not shown). The transmission medium may be wired or wireless. Based upon the disclosure provided herein, one of ordinary skill in the art will recognize a variety of source from which analog input signal 608 may be derived.

Analog to digital converter circuit 615 converts processed analog signal 612 into a corresponding series of digital samples 617. Analog to digital converter circuit 615 may be any circuit known in the art that is capable of producing digital samples corresponding to an analog input signal. Based upon the disclosure provided herein, one of ordinary skill in the art will recognize a variety of analog to digital converter circuits that may be used in relation to different embodiments of the present invention.

Digital samples 617 are provided to an equalizer circuit 620 that equalizes the received data and provides an equalized output 622. Equalized output 622 is provided to a sample buffer circuit 675 and subsequently to a data detector circuit 625. Sample buffer circuit 675 includes sufficient memory to maintain one or more codewords until processing of that codeword is completed through data detector circuit 625 and a data decoder circuit 650 including, where warranted, multiple “global iterations” defined as passes through both data detector circuit 625 and data decoder circuit 650 and/or “local iterations” defined as passes through data decoding circuit 650 during a given global iteration. Sample buffer circuit 675 stores the received data as buffered data 677.

Data detector circuit 625 is a data detector circuit capable of producing a detected output 627 by applying a data detection algorithm to a data input. As some examples, the data detection algorithm may be but is not limited to, a Viterbi algorithm detection algorithm or a maximum a posteriori detection algorithm as are known in the art. Based upon the disclosure provided herein, one of ordinary skill in the art will recognize a variety of data detection algorithms that may be used in relation to different embodiments of the present invention. Data detector circuit 625 may provide both hard decisions and soft decisions. The terms “hard decisions” and “soft decisions” are used in their broadest sense. In particular, “hard decisions” are outputs indicating an expected original input value (e.g., a binary ‘1’ or ‘0’, or a non-binary digital value), and the “soft decisions” indicate a likelihood that corresponding hard decisions are correct. Based upon the disclosure provided herein, one of ordinary skill in the art will recognize a variety of hard decisions and soft decisions that may be used in relation to different embodiments of the present invention. Related to FIG. 6, the detector output signal 627 is the detector extrinsic LLR/soft value, and signal 626 is the sum of detector extrinsic and decoder extrinsic LLR.

Detected output 627 is provided to an adder circuit 653 that adds detected output 627 to cross codeword soft data adjustment value 684 to yield soft data input 655. Soft data input 655 is scaled by a multiplier circuit 657 multiplying a modified soft data input 655 by a scaling input 658 to yield a scaled output 659. Any scaling input 658 known in the art may be used in relation to different embodiments of the present invention. During standard processing, soft data input 655 is the same as detected output 627 as a cross codeword soft data adjustment value 684 is set to zero. In contrast, during extended cross codewords error correction decoding (indicated by assertion of a cross codewords correction mode selection 681), cross codeword decoding soft data adjustment value 684 is set to an adjustment value calculated by a cross codewords error correction circuit 680 based upon a decoded output 651 and a detected output 626. Specifics of the calculations applied by cross codewords error correction circuit 680 are discussed below. Scaled output 659 is provided to a central queue memory circuit 660 that operates to buffer data passed between data detector circuit 625 and data decoder circuit 650. When data decoder circuit 650 is available, data decoder circuit 650 receives scaled output 659 from central queue memory 660 as a decoder input 656.

Data decoder circuit 650 applies a data decoding algorithm to decoder input 656 in an attempt to recover originally written data. The result of the data decoding algorithm is provided as a decoded output 654. Similar to detected output 627, decoded output 654 may include both hard decisions and soft decisions. For example, data decoder circuit 650 may be any data decoder circuit known in the art that is capable of applying a decoding algorithm to a received input. Data decoder circuit 650 may be, but is not limited to, a low density parity check decoder circuit or a turbo code decoder circuit as are known in the art. Based upon the disclosure provided herein, one of ordinary skill in the art will recognize a variety of data decoder circuits that may be used in relation to different embodiments of the present invention. Where the original data is recovered (i.e., the data decoding algorithm converges) or a timeout condition occurs, data decoder circuit 650 provides the result of the data decoding algorithm as a data output 674. Data output 674 is provided to a hard decision output circuit 696 where the data is reordered before providing a series of ordered data sets as a data output 698.

One or more iterations through the combination of data detector circuit 625 and data decoder circuit 650 may be made in an effort to converge on the originally written data set. As mentioned above, processing through both the data detector circuit and the data decoder circuit is referred to as a “global iteration”. For the first global iteration, data detector circuit 625 applies the data detection algorithm without guidance from a decoded output. For subsequent global iterations, data detector circuit 625 applies the data detection algorithm to buffered data 677 as guided by decoded output 654. A derivative of decoded output 654 is received from central queue memory 660 as a detector input 629. In particular, detector input 629 is scaled by a multiplier circuit 663 multiplying a modified soft data input 662 by a scaling input 665. Any scaling input 665 known in the art may be used in relation to different embodiments of the present invention. During standard processing, soft data input 662 is the same as decoded output 654 as a cross codeword soft data adjustment value 682 is set to zero. Thus, when an adder circuit 661 adds soft data 664 (i.e., decoded output 654), you get soft data 664 as soft data input 662. In contrast, during extended cross codewords error correction decoding (indicated by assertion of a cross codewords correction mode selection 681), cross codeword decoding soft data adjustment value 682 is set to an adjustment value calculated by a cross codewords error correction circuit 680 based upon decoded output 651 and detected output 626. Specifics of the calculations applied by cross codewords error correction circuit 680 are discussed below.

In some embodiments where data was originally scrambled using the scrambler circuit (i.e., where the cross codewords error correction codeword was scrambled) discussed above in relation to one of FIG. 2a and FIG. 4a, soft data input 629 is provided to a scrambler circuit (not shown) that is used to re-scramble the data elements that were scrambled using the scrambler circuit discussed above in relation to one of FIG. 2a and FIG. 4a. Of note, as the user data codewords are not scrambled and the cross codewords error correction codeword is scrambled in some cases, then in those cases the cross codewords error correction codeword is descrambled and no descrambling is applied to the user data codewords. In addition, detected output 626 and detected output 627 in some embodiments are provided to a de-scrambler circuit (not shown) to descramble the cross codewords information where scrambling is applied in the circuits discussed above in relation to one of FIG. 2a and FIG. 4a.

During each global iteration it is possible for data decoder circuit 650 to make one or more local iterations including application of the data decoding algorithm to decoder input 656. For the first local iteration, data decoder circuit 650 applies the data decoder algorithm without guidance from a decoded output 652. For subsequent local iterations, data decoder circuit 650 applies the data decoding algorithm to decoder input 656 as guided by a previous decoded output 652. In some embodiments of the present invention, a default of ten local iterations is allowed for each global iteration.

When cross codewords correction mode is selected by asserting cross codeword correction mode selection 681, cross codewords error correction circuit 680 calculates cross codeword soft data adjustment value 682 and cross codeword soft data adjustment value 684. The calculations are performed in accordance with the following equations:

LLR_{CCECC,in}=LLR_{Det,ext}+LLR_{Dec,ext},

sign{LLR_{CCECC,ext}}=AccumulatedCrossCodewordsSyndrome+xor(sign{LLR_{CCECC,in}[All Other Failed Sectors]});

and

|LLR_{CCECC,ext}|=min(|LLR_{CCECC,in}[All Other Failed Sectors]|).

LLR is soft data also known in the art as log likelihood ratio data. LLR_{CCECC,in} is the prior soft data for the cross codewords error correction decoding, LLR_{CCECC,ext} is the extrinsic soft data for the cross codewords error correction decoding, xor(sign{LLR_{CCECC,in}[All Other Failed Sectors]}) is the XOR of the signs of LLR_{CCECC,in} of all of the other failed codewords, and the AccumulatedCrossCodewordsSyndrome is the cross codeword error correction partial syndrome computed by XORing the bits in bit positions that are protected by the cross codewords error correction coding of converged user codewords and/or the converged cross codeword error correction codeword. Using data processing circuit 600 of FIG. 6 as an example, the cross codeword soft data adjustment value 682 and cross codeword soft data adjustment value 684 are only valid for data portion that are protected by the cross codewords error correction coding.

Again, cross codeword soft data adjustment value 682 is added to the soft data from data decoder circuit 650, and the resulting updated detector guide (as used herein, the detector guide is derived from the detector prior LLR) provided as detector input 629 is calculated in accordance with the following equation:

Updated Detector Guide=(LLR_{CCECC,ext}+LLR_{Dec,ext})×Scaling Factor,

where LLR_{Dec,ext} is the extrinsic soft data resulting from application of the data decoder algorithm. In the preceding applications of the data detector algorithm where cross codeword soft data adjustment value 682 was set to zero, the resulting detector guide provided as detector input 629 is calculated in accordance with the following equation:

Detector Guide=(LLR_{Dec,ext})×Scaling Factor.

Thus, during application of the data detector algorithm, soft data generated based upon the cross codewords error correction codeword is used to reprocess the failed codewords.

Cross codeword soft data adjustment value 684 is added to the soft data from data detector circuit 625, and the resulting updated decoder guide (as used herein, the decoder guide is derived from the decoder prior LLR) provided as decoder input 656 is calculated in accordance with the following equation:

Updated Decoder Guide=(LLR_{CCECC,ext}+LLR_{Det,ext})×Scaling Factor,

where LLR_{Det,ext} is the extrinsic soft data resulting from application of the data detector algorithm. In the preceding applications of the data decoder algorithm where cross codeword soft data adjustment value 684 was set to zero, the decoder guide was:

Decoder Guide=(LLR_{Det,ext})×Scaling Factor.

Thus, during application of the data decoder algorithm, soft data generated based upon the cross codewords error correction codeword is used to reprocess the failed data sectors.

Turning to FIGS. 7a-7b, flow diagrams 700, 701 show a method in accordance with various embodiments of the present inventions for applying first attempt data decoding in accordance with some embodiments of the present inventions. Following flow diagram 700 of FIG. 7a, it is determined whether a data set is ready for application of a data detection algorithm (block 705). In some cases, a data set is ready when it is received from a data decoder circuit via a central memory circuit. In other cases, a data set is ready for processing when it is first made available from an front end processing circuit. Where a data set is ready (block 705), it is determined whether a data detector circuit is available to process the data set (block 710).

Where the data detector circuit is available for processing (block 710), the data set is accessed by the available data detector circuit (block 715). The data detector circuit may be, for example, a Viterbi algorithm data detector circuit or a maximum a posteriori data detector circuit. Where the data set is a newly received data set (i.e., a first global iteration), the newly received data set is accessed. In contrast, where the data set is a previously received data set (i.e., for the second or later global iterations), both the previously received data set and the corresponding decode data available from a preceding global iteration (available from a central memory) is accessed. Where available (i.e., on a second or later global iteration), the corresponding decoded output is provided as a detector guide (block 725). The accessed data set is then processed by application of a data detection algorithm to the data set guided, where available, by the detector guide (block 730). Where the data set is a newly received data set (i.e., a first global iteration), it is processed without guidance from decode data available from a data decoder circuit. Alternatively, where the data set is a previously received data set (i.e., for the second or later global iterations), it is processed with guidance of corresponding decode data available from preceding global iterations. Application of the data detection algorithm yields a detected output, and a derivative of the detected output is stored to the central memory (block 735). The derivative of the detected output may be, for example, an interleaved or shuffled version of the detected output.

In parallel to the previously described data detection process, it is determined whether a data decoder circuit is available (block 706). The data decoder circuit may be, for example, a low density data decoder circuit applying a belief-propagation data decode algorithm as are known in the art. Where the data decoder circuit is available (block 706), a previously stored derivative of a detected output is accessed from the central memory and used as a received codeword (block 711). A low density data decoding algorithm is applied to the received codeword to yield a decoded output (block 716).

It is determined whether the decoded output converged (i.e., all parity checks were resolved) (block 721). Where the decoded output converged (block 721), the hard decisions from the decoded output are provided as an interleaved decoded output (block 746). The interleaved decoded output includes data that is shuffled (i.e., interleaved). The interleaved decoded output is de-interleaved to remove the shuffling and thereby yield a decoded output (block 751). The syndrome of the cross codewords error correction codeword is updated to reflect the converged codeword (block 756). As such, the updated syndrome represents the errors remaining in the cross codewords error correction codeword due to the non-converged LDPC codewords associated with the cross codewords error correction codeword.

Alternatively, where the decoded output failed to converge (block 721), it is determined if another local iteration is desired (block 726). Where another local iteration is desired (block 726), the next iteration through the data decoder circuit is applied. When another local iteration is not allowed (block 726), it is determined whether another global iteration is desired (block 761). Where another global iteration is desired (block 761), the decoded output is stored to the central memory to await re-application of the data detection algorithm discussed above in relation to FIG. 7a.

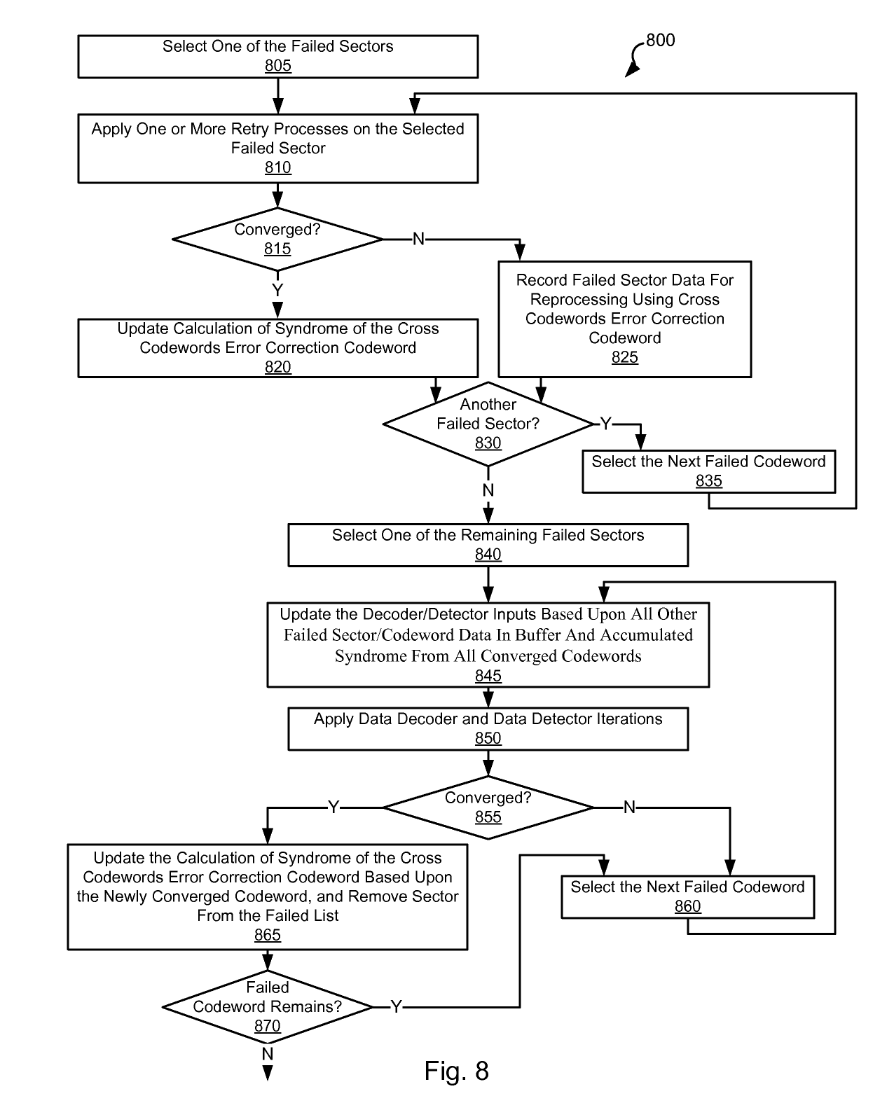

In contrast, where another global iteration is not allowed (block 736), the failed sector data is stored for reprocessing using retry processes (block 736). In some cases this may include storing the previously read data set to a memory for quick access during reprocessing using retry techniques. Alternatively, this may include storing an identifier of the failed sector that facilitates a re-read of the sector of data for reprocessing using retry techniques. The failed sector of data is then subjected to retry and/or cross codewords error correction aided decoding (block 741). Block 741 is shown in dashed lines as different embodiments of the process included in block 741 are described below in relation to FIGS. 8 and 9.

Turning to FIG. 8, a flow diagram 800 shows a method in accordance with various embodiments of the present inventions for applying soft data based cross codeword decoding. Following flow diagram 800, one of the failed sectors identified by block 736 of FIG. 7b is selected for re-processing (block 805). One or more retry processes are applied to the selected failed sector in an attempt to recover the previously stored codeword (block 810). Any retry process or processes known in the art may be applied in accordance with different embodiments of the present invention. Such retry processing may include, for example, changing one or more parameters such as gain values or coefficient values, and then re-applying global iterations of a data processing circuit.

It is determined whether the result of the retry processing converged (block 815). Where the result of the retry processing converged (block 815), the syndrome is that of the cross codewords error correction codeword updated to account for the newly converged codeword (i.e., the syndrome of the result is added to the syndrome of block 756 of FIG. 7b) (block 820). Alternatively, where the result of the retry processing failed to converge (block 815), the failed sector data is stored for reprocessing using retry processes (block 825). In some cases this may include storing the previously read data set to a memory for quick access during reprocessing using cross codewords error correction processes. Alternatively, this may include storing an identifier of the failed sector that facilitates a re-read of the sector of data for reprocessing using cross codewords error correction processes.

In either case, it is determined whether another failed sector remains to be reprocessed (block 830). Where another failed sector remains for reprocessing (block 830), the next failed codeword is selected (block 835) and the processes of blocks 810-830 are repeated for the next failed codeword.

Where no additional failed sectors remain to be reprocessed (block 830), cross codewords error correction is applied to the remaining failed sectors. This cross codewords error correction includes selecting one of the remaining failed sectors (block 840), and updating the decoder/detector inputs based upon all the other failed sector/codeword data in the buffer and accumulated syndrome from all converged codewords (block 845). This updating is done in accordance with the following equations:

LLR_{CCECC,in}=LLR_{Det,ext}+LLR_{Dec,ext};

sign{LLR_{CCECC,ext}}=AccumulatedCrossCodewordsSyndrome+xor(sign{LLR_{CCECC,in}[All Other Failed Sectors]});

and

|LLR_{CCECC,ext}|=min(|LLR_{CCECC,in}[All Other Failed Sectors]|).

LLR is soft data also known in the art as log likelihood ratio data. LLR_{CCECC,in} is the prior soft data for the cross codewords error correction decoding, LLR_{CCECC,ext} is the extrinsic soft data for the cross codewords error correction decoding, xor(sign{LLR_{CCECC,in}[All Other Failed Sectors]}) is the XOR of the signs of LLR_{CCECC,in} of all of the other failed codewords, and the AccumulatedCrossCodewordsSyndrome is the cross codeword error correction partial syndrome computed by XORing the bits in bit positions that are protected by the cross codewords error correction coding of converged user codewords and/or the converged cross codeword error correction codeword. Using data processing circuit 600 of FIG. 6 as an example, the cross codeword soft data adjustment value 682 and cross codeword soft data adjustment value 684 are only valid for data portion that are protected by the cross codewords error correction coding.

Re-application of the data detector algorithm to the failed sector is guided by the following updated detector guide:

Updated Detector Guide=(LLR_{CCECC,ext}+LLR_{Dec,ext})×Scaling Factor,

where LLR_{Dec,ext} is the extrinsic soft data resulting from application of the data decoder algorithm. In the preceding applications of the data detector algorithm (i.e., during standard processing of FIGS. 7a-7b and retry processing of block 810), the detector guide was:

Detector Guide=(LLR_{Dec,ext})×Scaling Factor.

Thus, during application of the data detector algorithm, soft data generated based upon the cross codewords error correction codeword is used to reprocess the failed data sectors.

Re-application of the data decoder algorithm to the failed sector is guided by the following updated decoder guide:

Updated Decoder Guide=(LLR_{CCECC,ext}+LLR_{Det,ext})×Scaling Factor,

where LLR_{Det,ext} is the extrinsic soft data resulting from application of the data detector algorithm. In the preceding applications of the data decoder algorithm (i.e., during standard processing of FIGS. 7a-7b and retry processing of block 810), the decoder guide was:

Decoder Guide=(LLR_{Det,ext})×Scaling Factor.

Thus, during application of the data decoder algorithm, soft data generated based upon the cross codewords error correction codeword is used to reprocess the failed data sectors.

Global iterations of the data decoder algorithm and data detector algorithm are applied to the failed sector using the updated decoder guide and updated detector guide (block 850). These global iterations are similar to that discussed above in relation to FIGS. 7a-7b except that the data detector algorithm is guided by the updated detector guide and the data decoder algorithm is guided by the updated decoder guide.

It is determined whether the result of the global iterations converged (block 855). Where the global iterations converged (block 855), the syndrome of the result is accumulated with the syndromes of other converging codewords (i.e., the syndrome of the result is added to the accumulated syndromes of block 820, and the sector is removed from the failed sectors list (block 865). It is then determined whether any failed codewords or sectors remain (block 870). Where other failed sectors remain (block 870), the next failed codeword is selected (block 860) and the processes of blocks 845-870 are repeated for the next failed codeword.

The process set forth above in relation to FIG. 8 is ended where reprocessing the all of the failed codewords fails to result in conversion of any of the remaining failed codewords. Thus, for example, where five codewords remain non-converged and re-processing of all of the five codewords results in convergence of one or more of those codewords, but not all of the five codewords converged (block 870) then the processing continues. In contrast, where re-processing of all of the five codewords fails to result in convergence of any one of those codewords then processing is terminated regardless of whether additional failed codewords remain. In such a case, an error message is generated.

It should be noted that the various blocks discussed in the above application may be implemented in integrated circuits along with other functionality. Such integrated circuits may include all of the functions of a given block, system or circuit, or a subset of the block, system or circuit. Further, elements of the blocks, systems or circuits may be implemented across multiple integrated circuits. Such integrated circuits may be any type of integrated circuit known in the art including, but are not limited to, a monolithic integrated circuit, a flip chip integrated circuit, a multichip module integrated circuit, and/or a mixed signal integrated circuit. It should also be noted that various functions of the blocks, systems or circuits discussed herein may be implemented in either software or firmware. In some such cases, the entire system, block or circuit may be implemented using its software or firmware equivalent, albeit such a system would not be a circuit. In other cases, the one part of a given system, block or circuit may be implemented in software or firmware, while other parts are implemented in hardware.

In conclusion, the invention provides novel systems, devices, methods and arrangements for data processing. While detailed descriptions of one or more embodiments of the invention have been given above, various alternatives, modifications, and equivalents will be apparent to those skilled in the art without varying from the spirit of the invention. It should be noted that the decoding processes that are discussed in some cases rely on storing data temporarily where a sector failure occurs. Where insufficient memory exists, it is possible to implement a re-read scenario to apply the data processing relying on a cross codewords error correction codeword. Therefore, the above description should not be taken as limiting the scope of the invention, which is defined by the appended claims.

What is claimed is:

1. A data processing system, the system comprising:
a data processing circuit operable to receive a data set including a plurality of user data codewords and a cross codewords error correction codeword including encoding generated from the plurality of user data codewords; and
wherein the data processing circuit includes:
a cross codeword error correction circuit operable to calculate a soft data adjustment value based at least in part upon decoding using the cross codewords error correction codeword;
a data decoding circuit operable to apply a data decoding algorithm to at least one of the user data codewords guided by a decoder input generated in part from the soft data adjustment value.

2. The system of claim 1, wherein the soft data adjustment value is a first soft data adjustment value, and wherein the data processing circuit further comprises:
a data detector circuit operable to apply a data detection algorithm to at least one of the user data codewords guided by a detector input generated in part from the second soft data adjustment value.

3. The system of claim 2, wherein the data detector circuit provides a detector output, and wherein the decoder input is generated in part by adding the first soft data adjustment value to the detector output.

4. The system of claim 3, wherein the decoder input is generated by multiplying the result of adding the first soft data adjustment value to the detector output by a scaling value.

5. The system of claim 2, wherein the data decoding circuit provides a decoder output, and wherein the detector input is generated in part by adding the second soft data adjustment value to the decoder output.

6. The system of claim 5, wherein the detector input is generated by multiplying the result of adding the second soft data adjustment value to the decoder output by a scaling value.

7. The system of claim 6, wherein the scaling value is user programmable.

8. The system of claim 1, wherein the system is implemented as part of an integrated circuit.

9. The system of claim 1, wherein the system is implemented as part of a storage device, and wherein the storage device comprises:
a storage medium storing the plurality of user data codewords and the cross codewords error correction codeword; and
a read/write head assembly disposed in relation to the storage medium.

10. The system of claim 9, wherein data at each bit position of the plurality of each of the user data codewords are XORd as part of generating a value included at a corresponding bit position of the cross codewords error correction codeword.

11. The system of claim 1, wherein each of the user data codewords are low density parity check codewords, and wherein the cross codewords error correction codeword is generated prior to applying the low density parity check encoding that yields the user data codewords.

12. The system of claim 11, wherein the parity data added during the low density parity check encoding is not protected by the cross codewords error correction codeword.

13. The system of claim 1, wherein data decoding algorithm is a low density parity check decoding algorithm.

14. The system of claim 1, wherein the cross codewords error correction codeword incorporates two or more codewords shuffled together to distribute encoding protection across the two or more codewords.

15. The system of claim 1, cross codewords error correction codeword is scrambled, and wherein the data processing circuit further comprises:
a descrambling circuit operable to reverse the scrambling of the cross codewords error correction codeword.

16. The system of claim 1, wherein systematic run length limited encoding is applied to the cross codewords error correction codeword.

17. The system of claim 1, wherein the user data codewords are low density parity check codewords, and wherein the cross codewords error correction codeword protects all elements of the user data codewords when the low density parity check code is linear and all of the low density parity check codewords use the same decoding matrix.

18. A method for data processing, the method comprising:
receiving a data set including a plurality of user data codewords and a cross codewords error correction codeword including encoding generated from the plurality of user data codewords;
calculating, using a cross codeword error correction circuit, a soft data adjustment value based at least in part upon the cross codewords error correction codeword; and
applying a data decoding algorithm to at least one of the user data codewords guided by a decoder input generated in part from the soft data adjustment value.

19. The method of claim 18, wherein the soft data adjustment value is a first soft data adjustment value, and wherein the method further comprises:
applying a data detection algorithm to at least one of the user data codewords guided by a detector input generated in part from the second soft data adjustment value.

20. The method of claim 19, wherein applying the data detection algorithm yields a detector output, and wherein the decoder input is generated in part by adding the first soft data adjustment value to the detector output.

21. The method of claim 20, wherein the decoder input is generated by multiplying the result of adding the first soft data adjustment value to the detector output by a scaling value.

22. The method of claim 18, wherein the method further comprises:
accumulating a partial syndrome of converged user data codewords and/or the cross codewords error correction codeword.

23. The method of claim 22, wherein applying the data decoding algorithm to at least one of the user data codewords guided by the decoder input generated in part from the soft data adjustment value comprises:
selecting a failed user data codeword from a failed codeword list for extended cross codeword error correction decoding;
applying the data decoding algorithm using use soft data adjustment value generated from the accumulated partial syndrome and other failed codeword data, wherein the first user data codeword converges; and
updating the accumulated partial syndrome to remove the first user data codeword from the failed codeword list.

24. The method of claim 23, wherein the failed user data codeword is a first failed user data codeword, the method further comprising:
selecting a second user data codeword from the failed codeword list for extended cross codeword error correction decoding;
applying the data decoding algorithm using use soft data adjustment value generated from the accumulated partial syndrome and other failed codeword data, wherein the second user data codeword converges;
updating the accumulated partial syndrome to remove the second user data codeword from the failed codeword list; and
wherein a next user data codeword from the failed codeword list for extended cross codeword error correction decoding is repeatedly selected and processed until either the failed codeword list for extended cross codeword error correction decoding does not change between processing of next selected codewords or the failed codeword list for extended cross codeword error correction decoding is empty.

25. The method of claim 18, the method further comprising:
buffering failed sector data for extended cross codeword error correction decoding.

26. A data processing system, the system comprising:
a means for receiving a data set including a plurality of user data codewords and a cross codewords error correction codeword including encoding generated from the plurality of user data codewords; and
wherein the means for receiving the data set includes:
a means for calculating a soft data adjustment value based at least in part upon the cross codewords error correction codeword; and
a means for applying a data decoding algorithm to at least one of the user data codewords guided by a decoder input generated in part from the soft data adjustment value.
